(19) United States
(12) Patent Application Publication
(10) Pub. No.: US 2007/0062810 A1
(43) Pub. Date: Mar. 22, 2007

(54) SPUTTERING SYSTEM USING SILVER-BASED ALLOY

(75) Inventors: Bernd Gehlert, Bruchköbel (DE); Heiko Specht, Aschaffenburg (DE); Oliver Warkentin, Darmstadt (DE)

Correspondence Address: AKIN GUMP STRAUSS HAUER & FELD L.L.P., ONE COMMERCE SQUARE, 2005 MARKET STREET, SUITE 2200, PHILADELPHIA, PA, 19103, US

(73) Assignee: W.C. HERAEUS GMBH & CO., KG, Hanau (DE)

(21) Appl. No.: 11/557,265

(22) Filed: Nov. 7, 2006

Related U.S. Application Data
(62) Division of application No. 10/866,945, filed on Jun. 14, 2004.

(30) Foreign Application Priority Data
Jun. 16, 2003 (DE) 103 27 336.0-24

(51) Int. Cl. C23C 14/00

(52) U.S. Cl. 204/298.13

(57) ABSTRACT

An alloy based on silver is provided, which can be used for reflective layers with a reflection factor of >90% in the visible spectral range of daylight and which exhibits a high resistance to corrosion in sulfur-containing atmospheres. The alloy contains about 0.01 to 5 wt % indium and/or tin and/or antimony and/or bismuth and the remainder silver.

### CROSS-REFERENCE TO RELATED APPLICATIONS

This is a division of co-pending application Ser. No. 10/866,945, filed Jun. 14, 2004, the disclosure of which is incorporated herein by reference.

### BACKGROUND OF THE INVENTION

The invention relates to an alloy based on silver and also to its use.

European published patent application EP 1 028 421 A2 discloses a multi-layered optical disc with at least two layers for data recording, which are covered with a transparent layer as well as a light-transmitting protective layer. Here, at least one of the two layers for data recording includes at least one element from a group including, among many others, the elements silver, gold, tin, aluminum, copper, ruthenium, rhodium, and indium.

International application publication WO 99/67084 discloses metal alloys for reflective or semi-reflective layers of an optical storage medium. Here, silver-palladium-copper and silver-palladium-rhodium alloys are cited in particular as metal alloys.

European published patent application EP 1 103 758 A2 discloses a reflective layer for a lamp, the layer being made of a silver-palladium-copper alloy, wherein the palladium content lies in the range of 0.5 to 3.0 wt % and the copper content lies in the range of 0.1 to 3 wt %. Further disclosed is the preparation of a sputtering target or a vaporizable material from the silver-palladium-copper alloy.

European published patent application EP 1 069 194 A1 discloses a metal alloy for electronic parts with 0.1 to 3.0 wt % palladium, 0.1 to 3.0 wt % copper, and the remainder silver. Further disclosed is to use the metal alloy for a sputtering target.

German Patent DE 41 35 801 C2 discloses a reflective layer made of silver on a glass substrate. The reflective layer is treated for corrosion protection on the side facing away from the glass substrate with an aqueous solution of a chloride, bromide, iodide, sulfate, or acetate of at least Al³⁺, Ti³⁺, V²⁺, V³⁺, Cr²⁺, Fe²⁺, In²⁺, Cu²⁺. Furthermore, Sn(II) ions can be contained in the aqueous solution. A glass substrate coated in this way can be used, among other things, as a mirror.

German Patent DE 41 35 800 C2 discloses a reflective layer made of silver on a glass substrate. The reflective layer is treated for corrosion protection on the side facing away from the glass substrate with a freshly produced, acidified, aqueous solution of a tin (II) chloride, tin (III) bromide, tin (II) iodide, tin (II) sulfate, or tin (II) acetate. The reflective layer made of silver has, after this treatment on its side facing away from the glass substrate, a surface layer with a thickness in the range of 2 to 3 nm, which has at least an increased number of tin atoms in the range of 5 to 35 atoms of tin (Sn) per 100 atoms of metal, which corresponds to a percentage of greater than 5.5 wt % Sn. A glass substrate coated in this way can be used, among other things, as a mirror.

International application publication WO 00/69975 discloses a method for producing metal flakes with dielectric coating. Here, the material for the metal flakes or a reflective metal layer is selected from the group of Al, Cu, Ag, Au, Pt, Pd, Ni, Co, Sn, Rh, Nb, Cr, their combinations, or their alloys. The reflective metal layer is covered on both sides with a dielectric layer and is finally ground to produce flake pieces.

### BRIEF SUMMARY OF THE INVENTION

Now, the problem of the invention is to provide an alloy based on silver, which can be used for reflective layers with a reflection factor of >90% in the visible spectral range of daylight and here exhibits a high corrosion resistance to sulfur-containing atmospheres.

The problem is solved in that the alloy comprises about 0.01 to 5 wt % indium and/or tin and/or antimony and/or bismuth and the remainder silver.

In particular, an alloy is preferred which comprises about 0.5 to 3 wt % indium and/or tin and/or antimony and/or bismuth and the remainder silver.

An alloy which has here proven to be especially effective is made of about 0.5 to 1 wt % indium and/or tin and/or antimony and/or bismuth and the remainder silver, particularly made of:

about 0.5 wt % tin and the remainder silver, or

about 1 wt % tin and the remainder silver, or

about 0.5 wt % indium and the remainder silver, or

about 1 wt % indium and the remainder silver, or

about 0.5 wt % tin, 0.5 wt % indium and the remainder silver.

The resistance of these alloys to atmospheric corrosion was tested by subjecting a thin layer formed by cathode sputtering, and also comparison layers according to the prior art, to the following climatic test:

H₂S corrosive gas test:

A first comparison layer made of pure silver (Ag), a second comparison layer with 98 wt % silver, 1 wt % palladium, and 1 wt % copper (AgPd1Cu1), as well as the following layers made of an alloy according to the invention were exposed at a temperature of 25° C. to a corrosive gas with a relative air humidity of 75% and an H₂S content of 1 ppm:

99.5 wt % silver, 0.5 wt % indium (AgIn0.5);

99.0 wt % silver, 1.0 wt % indium (AgIn1);

99.0 wt % silver, 0.5 wt % tin, 0.5 wt % indium (AgSn0.5In0.5);

99.5 wt % silver, 0.5 wt % tin (AgSn0.5);

99.0 wt % silver, 1.0 wt % tin (AgSn1);

97.0 wt % silver, 3.0 wt % tin (AgSn3).

### BRIEF DESCRIPTION OF THE SEVERAL VIEWS OF THE DRAWINGS

The foregoing summary, as well as the following detailed description of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown. In the drawings:

FIG. 1 is a series of graphs showing reflection of various test layers at 560 nm measured before the corrosive gas test as well as after a corrosive gas test period of 3 h and 6 h;

FIG. 2 is a series of graphs showing the reflection (in %) of comparison layers made of Ag (curve A) and AgPd1Cu1 (curve D) compared with layers made of the alloys AgIn0.5 (curve B) and AgSn0.5 (curve C), according to the invention, for wavelengths in the range of the visible spectrum.

### DETAILED DESCRIPTION OF THE INVENTION

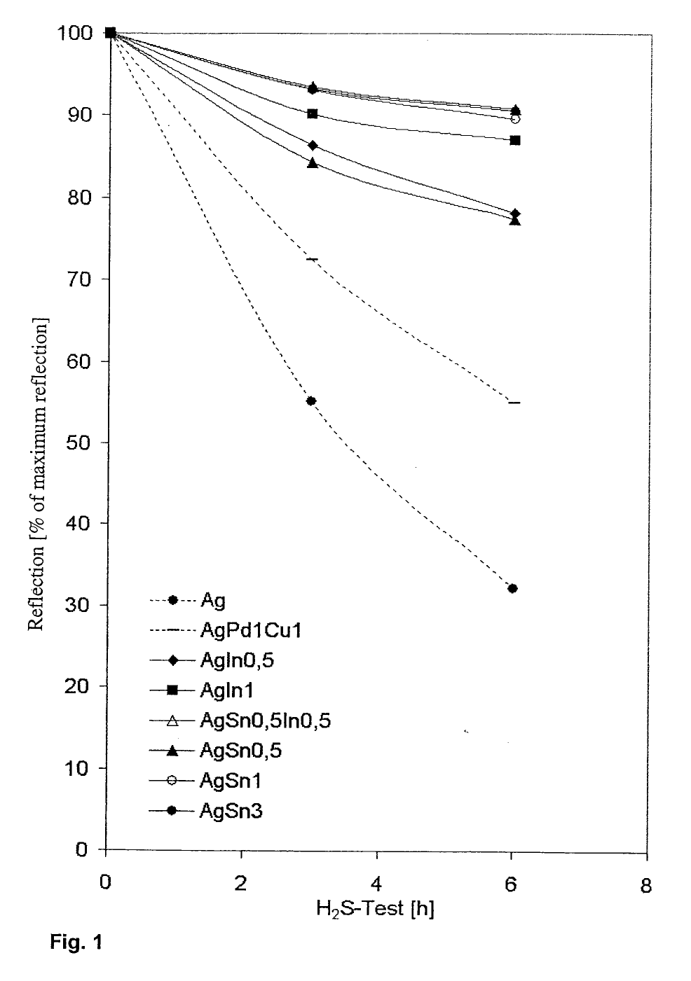

In order to determine the resistance to atmospheric corrosion quantitatively, the reflection of the layers at 560 nm was measured before the corrosive gas test as well as after a corrosive gas test period of 3 h and 6 h (see FIG. 1). Here, the measurement results of each layer were normalized to the value of its reflection before the climatic test. For all layers this test showed a drop of the reflection factor as a function of the period of the corrosive gas test. It can be recognized that the reflective layers made of alloys according to the invention are clearly superior in resistance to atmospheric corrosion to known layers made of Ag or AgPd1Cu1. The layers made of AgSn1 and AgSn0.5In0.5 have proven here to be especially resistant to atmospheric corrosion.

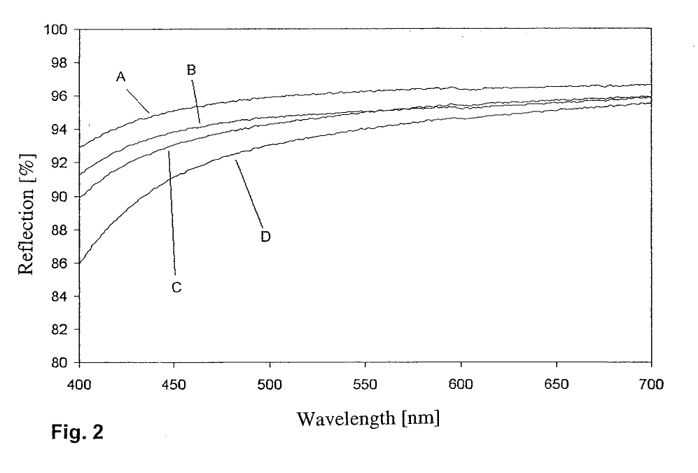

The use of the alloys according to the invention for forming reflective layers is ideal. In particular, as reflective layers, the alloys AgIn0.5 and AgSn0.5 have the advantage of a higher reflection factor relative to known materials for reflective layers, such as AgPd1Cu1. In FIG. 2 the reflection (in %) of the comparison layers made of Ag (curve A) and AgPd1Cu1 (curve D) is compared with the layers made of the alloys AgIn0.5 (curve B) and AgSn0.5 (curve C), according to the invention, for wavelengths in the range of the visible spectrum. The improved reflection of the layers made of the alloys according to the invention relative to the comparison layer made of AgPd1Cu1 (curve D) can be clearly recognized.

Since the alloys according to the invention also exhibit an improved corrosion behavior, it is determined that a reflective layer made of such an alloy represents an excellent alternative, which is to be preferred in terms of reflection factor, to known reflective layers.

In particular, the use as a reflective layer for reflection of visible daylight is preferred. Especially suited is the reflective layer for reflection of visible daylight in reflective or transflective displays. Because no additional electrical backlighting is provided in reflective displays, these require an especially high reflection factor of the reflective layer, which a layer made of an alloy according to the invention has to a large degree. With the use of an alloy according to the invention for reflective layers, it is especially to be stressed that subsequent treatment of the reflective layer, for example by chemical, mechanical, or coating methods, can be eliminated.

Furthermore, a use of the alloy as a reflective layer for optical storage media is ideal.

The use of alloys according to the invention for forming a sputtering material for cathode sputtering systems has proven especially effective. Since reflective layers for optical storage media and in reflective displays are usually formed by PVD (physical vapor deposition), it is helpful to make the alloy available as sputtering material or as a sputter target or as vaporization material.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

We claim:

1. In a sputtering system having a cathode sputtering target, the improvement comprising utilizing as a sputtering material for a sputtering target an alloy based on silver, wherein the alloy comprises about 0.01 to 5 wt % of at least one metal selected from the group consisting of indium, tin, antimony, and bismuth, and a remainder of the alloy comprises silver.

2. The sputtering system according to claim 1, wherein the alloy comprises about 0.5 to 3 wt % of at least one metal selected from the group consisting of indium, tin, antimony, and bismuth, and the remainder of the alloy comprises silver.

3. The sputtering system according to claim 2, wherein the alloy comprises about 0.5 to 1 wt % of at least one metal selected from the group consisting of indium, tin, antimony, and bismuth, and the remainder of the alloy comprises silver.

4. The sputtering system according to claim 3, wherein the alloy comprises about 0.5 wt % tin and the remainder of the alloy comprises silver.

5. The sputtering system according to claim 3, wherein the alloy comprises about 1 wt % tin and the remainder of the alloy comprises silver.

6. The sputtering system according to claim 3, wherein the alloy comprises about 0.5 wt % indium and the remainder of the alloy comprises silver.

7. The sputtering system according to claim 3, wherein the alloy comprises about 1 wt % indium and the remainder of the alloy comprises silver.

8. The sputtering system according to claim 3, wherein the alloy comprises about 0.5 wt % tin, 0.5 wt % indium, and the remainder of the alloy comprises silver.
